(19) United States
(12) Patent Application Publication
(10) Pub. No.: US 2007/0145534 A1
(43) Pub. Date: Jun. 28, 2007

(54) Reference voltage generating circuit and semiconductor integrated circuit using the reference voltage generating circuit

(76) Inventor: Hideaki Murakami, Hyogo (JP)

Correspondence Address: COOPER & DUNHAM, LLP, 1185 AVENUE OF THE AMERICAS, NEW YORK, NY, 10036, US

(21) Appl. No.: 11/641,220

(22) Filed: Dec. 18, 2006

(30) Foreign Application Priority Data
Dec. 21, 2005 (JP) 2005-368149

(51) Int. Cl. H01L 27/082

(52) U.S. Cl. 257/566

(57) ABSTRACT

A reference voltage generating circuit is disclosed. The reference voltage generating circuit includes a collector layer where collectors of transistors are disposed, a base layer where bases of the transistors are disposed and which base layer is formed on the surface of the collector layer, and plural emitter layers in each of which an emitter of the transistor is disposed and which emitter layers are formed on the surface of the base layer that is common to the emitter layers.

### BACKGROUND OF THE INVENTION

1. Field of the Invention

The present invention generally relates to a reference voltage generating circuit which is used as a power source circuit of a semiconductor integrated circuit; and in particular, a bandgap reference circuit.

2. Description of the Related Art

Generally, a reference voltage generating circuit for a semiconductor integrated circuit is formed of bipolar transistors.

FIG. 6 is a circuit diagram of a bandgap reference circuit. A bandgap reference circuit utilizes characteristics of a base-emitter voltage Vbe and a change of the base-emitter voltage ΔVbe of a bipolar transistor and does not have temperature dependency. Therefore, the bandgap reference circuit is used as a reference voltage generating circuit.

In FIG. 6, two PNP transistor groups Q1 and Q2 whose collectors and bases are grounded are disposed in the reference voltage generating circuit. The PNP transistor group Q1 includes plural PNP transistors and also the PNP transistor group Q2 includes plural PNP transistors. Resistors RE3 and RE2 are connected to the emitters of the PNP transistor group Q2 in series in this order. A resistor RE1 is connected to the emitters of the PNP transistor group Q1. A connection point of the emitters of the PNP transistor group Q1 with the resistor RE1 and a connection point of the resistor RE3 with the resistor RE2 are connected to corresponding input terminals of an amplifier AMP. A connection point of the resistor RE2 with the resistor RE1 is connected to an output terminal of the amplifier AMP. A voltage output terminal VOUT is connected to the output terminal of the amplifier AMP.

FIG. 7 is a diagram showing an arrangement of PNP transistors in the bandgap reference circuit shown in FIG. 6. That is, the PNP transistor groups Q1 and Q2 shown in FIG. 6 are composed of the PNP transistors shown in FIG. 7. In patent Document 1, a semiconductor device is disclosed and FIGS. 6 and 7 are shown therein.

As shown in FIG. 7, in the PNP transistor group Q1 or Q2, an emitter electrode 12 is disposed at the center of an emitter layer 8, a base layer 6 is formed around the emitter layer 8, and base electrodes 4 are disposed around the emitter layer 8. A collector layer 10 is common among the PNP transistors, and collector electrodes 2 are disposed around the base layer 6.

In the above bandgap reference circuit, a reference voltage Vout to be output is expressed by Equation (1), where resistance of the resistor RE1 is y, resistance of the resistor RE2 is x, an emitter-base voltage of the PNP transistor group Q1 is Vbe1, a total emitter area of the PNP transistor group Q1 is N, a total emitter area of the PNP transistor group Q2 is M, Boltzmann's coefficient is k, the absolute temperature at operations is T, and an elementary electric charge is q.
Vout=Vbe1+(y/x)×(kT/q)×logₑ(N/M) Equation(1)

As shown in Equation (1), the reference voltage Vout is changed by the resistance ratio (y/x) between the resistors RE1 and RE2 and the total emitter area ratio (N/M) between the PNP transistor groups Q1 and Q2. However, when the resistance ratio (y/x) is suitably determined, the reference voltage Vout does not depend on a temperature change.

However, in some cases, the reference voltage generating circuit (bandgap reference circuit) shown in FIG. 6 is used together with a digital circuit. In this case, when a frequency of the digital circuit is increased, the collector current is decreased inversely proportional to the frequency increase. That is, the collector current depends on frequency. In addition, the increase or decrease of the collector current is emphasized by base-collector parasitic capacitance and base-emitter parasitic capacitance.

In other words, the collector current is increased or decreased due to a change of the frequency of the digital circuit, the base-collector parasitic capacitance, and the base-emitter parasitic capacitance. That is, due to the above, output characteristics of the reference voltage Vout are degraded.

In FIG. 7, the PNP transistors are bipolar transistors, the base layers 6 are separated from each other, and the base electrodes 4 are disposed between the emitter layer 8 and the outer circumference of the base layer 6. In this case, due to the area of the base layer 6 and the length of the outer circumference of the base layer 6, the collector-base capacitance becomes relatively large.

In Patent Document 2, a bandgap voltage generating circuit is disclosed. In the bandgap voltage generating circuit, by limiting an emitter area which is a reference, process dispersion in the emitter area and resistance of the emitter are decreased. With this, a highly accurate current and a highly accurate bandgap reference voltage can be obtained. In Patent Document 3, a receiver circuit in compliance with the LVDS (low voltage differential signaling) standard is disclosed. The receiver circuit can output a received signal to an inner circuit whose power source voltage is different without using a level shift circuit.

[Patent Document 1] Japanese Laid-Open Patent Application No. 2001-267327 (Japanese Patent No. 3367500)

[Patent Document 2] Japanese Laid-Open Patent Application No. 6-151705

[Patent Document 3] Japanese Laid-Open Patent Application No. 2004-112424

### SUMMARY OF THE INVENTION

In a preferred embodiment of the present invention, there is provided a reference voltage generating circuit formed of bipolar transistor groups in which output characteristics are stable even if the circuit is used with a digital circuit and a semiconductor integrated circuit using the reference voltage generating circuit.

Features and advantages of the present invention are set forth in the description that follows, and in part will become apparent from the description and the accompanying drawings, or may be learned by practice of the invention according to the teachings provided in the description. Features and advantages of the present invention will be realized and attained by a reference voltage generating circuit and a semiconductor integrated circuit using the reference voltage generating circuit particularly pointed out in the specification in such full, clear, concise, and exact terms as to enable a person having ordinary skill in the art to practice the invention.

To achieve one or more of these and other advantages, according to one aspect of the present invention, there is provided a reference voltage generating circuit. The reference voltage generating circuit of a bandgap reference circuit includes a collector layer where collectors of transistors are disposed, a base layer where bases of the transistors are disposed and which base layer is formed on the surface of the collector layer, and plural emitter layers in each of which an emitter of the transistor is disposed and which emitter layers are formed on the surface of the base layer that is common to the emitter layers.

According to another aspect of the present invention, base electrodes of the bases of the transistors are disposed at inner circumference regions of the base layer.

According to another aspect of the present invention, the shape of the emitter layer is made octagonal by cutting off a corner part of the emitter layer having a square shape and base electrodes of the bases are disposed at the positions where the corner parts of the emitter layers are cut off.

According to another aspect of the present invention, the base electrodes are not disposed at the inner circumference regions of the base layer and the area of the base layer is narrowed so as to shorten the distance between the outer circumference of the base layer and the emitter layers.

According to another aspect of the present invention, the shape of the base layer is made octagonal by cutting off corner parts of the base layer having a square shape.

According to another aspect of the present invention, there is provided a semiconductor integrated circuit. The semiconductor integrated circuit includes a high-speed circuit and a reference voltage generating circuit. The reference voltage generating circuit includes a collector layer where collectors of transistors are disposed, a base layer where bases of the transistors are disposed and which base layer is formed on the surface of the collector layer, and plural emitter layers in each of which an emitter of the transistor is disposed and which emitter layers are formed on the surface of the base layer that is common to the emitter layers.

According to another aspect of the present invention, in the reference voltage generating circuit of the semiconductor integrated circuit, base electrodes of the bases of the transistors are disposed at inner circumference regions of the base layer.

According to another aspect of the present invention, in the reference voltage generating circuit of the semiconductor integrated circuit, the shape of the emitter layer is made octagonal by cutting off a corner part of the emitter layer having a square shape and base electrodes of the bases are disposed at the positions where the corner parts of the emitter layers are cut off.

According to another aspect of the present invention, in the reference voltage generating circuit of the semiconductor integrated circuit, the base electrodes are not disposed at the inner circumference regions of the base layer and the area of the base layer is narrowed so as to shorten the distance between the outer circumference of the base layer and the emitter layers.

According to another aspect of the present invention, in the reference voltage generating circuit of the semiconductor integrated circuit, the shape of the base layer is made octagonal by cutting off corner parts of the base layer having a square shape.

### EFFECT OF THE INVENTION

According to an embodiment of the present invention, in a reference voltage generating circuit of a bandgap reference circuit, collector-base parasitic capacitance can be decreased. Therefore, a frequency which affects a characteristic of a reference voltage can be moved toward a high-frequency region.

### BRIEF DESCRIPTION OF THE DRAWINGS

Features and advantages of the present invention will become more apparent from the following detailed description when read in conjunction with the accompanying drawings, in which:

FIG. 1 is a diagram showing an arrangement of PNP transistors in a reference voltage generating circuit according to a first embodiment of the present invention;

FIG. 2 is a diagram showing an arrangement of PNP transistors in a reference voltage generating circuit according to a second embodiment of the present invention;

FIG. 3 is a diagram showing an arrangement of PNP transistors in a reference voltage generating circuit according to a third embodiment of the present invention;

FIG. 4 is a diagram showing an arrangement of PNP transistors in a reference voltage generating circuit according to a fourth embodiment of the present invention;

FIG. 5 is a block diagram showing a semiconductor integrated circuit according to a fifth embodiment of the present invention;

FIG. 6 is a circuit diagram of a bandgap reference circuit; and

FIG. 7 is a diagram showing an arrangement of PNP transistors in the bandgap reference circuit shown in FIG. 6.

### DESCRIPTION OF THE PREFERRED EMBODIMENT

### Best Mode of Carrying Out the Invention

A best mode of carrying out the present invention is described with reference to the accompanying drawings.

As described above, the bandgap reference circuit shown in FIG. 6 is a reference voltage generating circuit having the following reference voltage Vout shown in Equation (1). Where resistance of the resistor RE1 is y, resistance of the resistor RE2 is x, an emitter-base voltage of the PNP transistor group Q1 is Vbe1, a total emitter area of the PNP transistor group Q1 is N, a total emitter area of the PNP transistor group Q2 is M, Boltzmann's coefficient is k, the absolute temperature at operations is T, and an elementary electric charge is q.
Vout=Vbe1+(y/x)×(kT/q)×logₑ(N/M) Equation (1)

As described above, when the resistance ratio (y/x) between the resistors RE1 and RE2 is suitably determined, the reference voltage Vout does not depend on a temperature change.

However, the following phenomenon is not expressed in Equation (1), that is, the reference voltage Vout is changed when a current flowing into the PNP transistor groups Q1 and Q2 is changed. The change of the current is caused by a frequency characteristic of the collector current. That is, the frequency of the digital circuit which is used together with the reference voltage generating circuit affects the change of the current.

A factor of the change of the current is described.

Generally, a frequency characteristic of a bipolar transistor which is used together with a digital circuit has a relationship shown in Equation (2).

$$\vert \frac{ic}{ib} \vert = \frac{gm}{ω ( Cbe + Ccb )} \qquad Equation ( 2 )$$

where ic is a collector current, ib is a base current, gm is transconductance, ω is a frequency (angular velocity), Cbe is base-emitter parasitic capacitance, and Ccb is collector-base parasitic capacitance.

From Equation (2), in a bipolar transistor, since the base current ib is generally almost constant, when the frequency ω is increased, the collector current ic is decreased inversely proportional to the increase of the frequency ω. In addition, the collector current ic having frequency dependency is increased or decreased by the collector-base parasitic capacitance Ccb and the base-emitter parasitic capacitance Cbe.

When the frequency dependency of the collector current ic is large, the collector current ic is changed by a change of the frequency ω. Consequently, the output characteristic of the reference voltage Vout is degraded. Similarly, when the collector-base parasitic capacitance Ccb and/or the base-emitter parasitic capacitance Cbe is large, the collector current is changed. Consequently, the output characteristic of the reference voltage Vout is degraded.

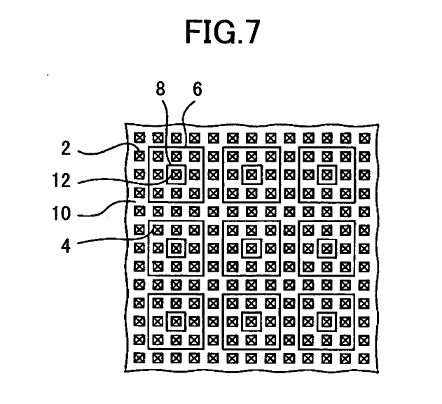

As described above, in the bipolar transistor (PNP transistor) group Q1 or Q2 shown in FIG. 7, the base layers 6 are separated from each other, the base electrodes 4 are disposed between the emitter layer 8 and the outer circumference of the base layer 6, and the area of the base layer 6 and the length of the outer circumference of the base layer 6 are relatively large. With this, the collector-base parasitic capacitance Ccb becomes relatively large and the collector current ic is changed. Consequently, the characteristic of the reference voltage Vout is degraded.

In the embodiments of the present invention, parasitic capacitance is decreased; especially, collector-base parasitic capacitance is decreased. With this, a frequency which affects the characteristic of the reference voltage Vout is moved toward a high-frequency region. In the embodiments of the present invention, as the reference number of each element, the same reference number as that shown in FIG. 7 is used.

### First Embodiment

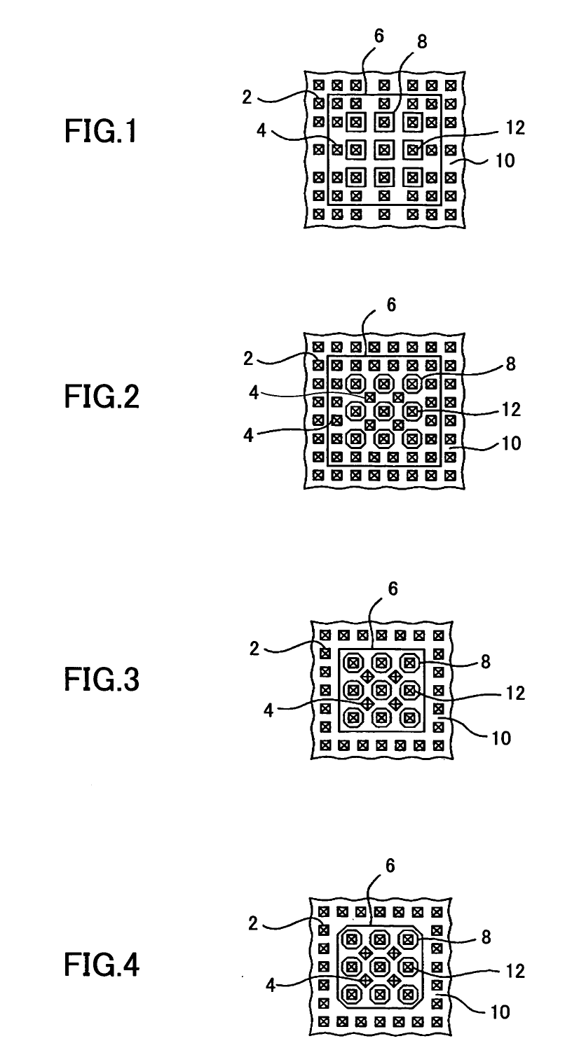

Referring to FIG. 1, a first embodiment of the present invention is described. FIG. 1 is a diagram showing an arrangement of PNP transistors in a reference voltage generating circuit according to the first embodiment of the present invention. In FIG. 1, as the reference voltage generating circuit, a bandgap reference circuit is used.

As shown in FIG. 1, bases of plural PNP transistors are disposed in a base layer 6. At the center of the base layer 6, emitter layers 8 and corresponding emitter electrodes 12 are disposed. Base electrodes 4 are disposed around the emitter layers 8. Further, a collector layer 10 is disposed around the base layer 6, and collector electrodes 2 are disposed around the base layer 6.

As described above, since the base layer 6 of the bases of the plural PNP transistors is one, collector-base parasitic capacitance in each PNP transistor can be decreased. Therefore, the frequency which affects the characteristic of the reference voltage Vout can be moved toward a high-frequency region.

### Second Embodiment

Referring to FIG. 2, a second embodiment of the present invention is described. FIG. 2 is a diagram showing an arrangement of PNP transistors in a reference voltage generating circuit according to the second embodiment of the present invention. In FIG. 2, as the reference voltage generating circuit, a bandgap reference circuit is used.

The second embodiment of the present invention is almost the same as the first embodiment of the present invention; therefore, only points different from the first embodiment are described.

As shown in FIG. 2, the shape of the emitter layer 8 is made octagonal by cutting off corner parts of the emitter layer 8 having a square shape shown in FIG. 1, and the base electrodes 4 are disposed at areas where the corner parts are cut off.

Therefore, the base-emitter parasitic capacitance can be decreased due to the above arrangement. Consequently, the frequency which affects the characteristic of the reference voltage Vout can be moved toward a high-frequency region.

### Third Embodiment

Referring to FIG. 3, a third embodiment of the present invention is described. FIG. 3 is a diagram showing an arrangement of PNP transistors in a reference voltage generating circuit according to the third embodiment of the present invention. In FIG. 3, as the reference voltage generating circuit, a bandgap reference circuit is used.

The third embodiment of the present invention is almost the same as the second embodiment of the present invention; therefore, only points different from the second embodiment are described.

As shown in FIG. 3, the base electrodes 4 disposed around the emitter layers 8 shown in FIG. 2 are removed. In addition, the base electrodes 4 disposed among the emitter layers 8 shown in FIG. 2 are rotated by approximately 45°. Further, the distance between the emitter layer 8 and the emitter electrode 12 is shortened and also the area of the base layer 6 is narrowed.

Therefore, the collector-base parasitic capacitance can be further decreased by narrowing the area of the base layer 6. Consequently, the frequency which affects the characteristic of the reference voltage Vout can be moved toward a high-frequency region.

### Fourth Embodiment

Referring to FIG. 4, a fourth embodiment of the present invention is described. FIG. 4 is a diagram showing an arrangement of PNP transistors in a reference voltage generating circuit according to the fourth embodiment of the present invention. In FIG. 4, as the reference voltage generating circuit, a bandgap reference circuit is used.

The fourth embodiment of the present invention is almost the same as the third embodiment of the present invention; therefore, only points different from the third embodiment are described.

As shown in FIG. 4, corner parts of the base layer 6 having a square shape shown in FIG. 3 are cut off. Therefore the area of the base layer 6 is further narrowed.

Therefore, the collector-base parasitic capacitance can be much further decreased by further narrowing the area of the base layer 6. Consequently, the frequency which affects the characteristic of the reference voltage Vout can be moved toward a high-frequency region.

As described above, in the reference voltage generating circuit shown in FIG. 7, the collector-base parasitic capacitance in the PNP transistor groups Q1 and Q2 is large. When a circuit which is operated at high speed, for example, a high-speed A/D converter, is integrated with a reference voltage generating circuit (bandgap reference circuit) on a chip, noise generated from the A/D converter is transmitted to PNP transistors via a substrate of the chip. Consequently, the frequency characteristic is degraded by the collector-base parasitic capacitance. In order to solve the above problem, as described in the first through fourth embodiments, the area of the base layer 6 for the plural PNP transistors is narrowed. With this, the frequency characteristic is improved by decreasing the collector-base parasitic capacitance.

### Fifth Embodiment

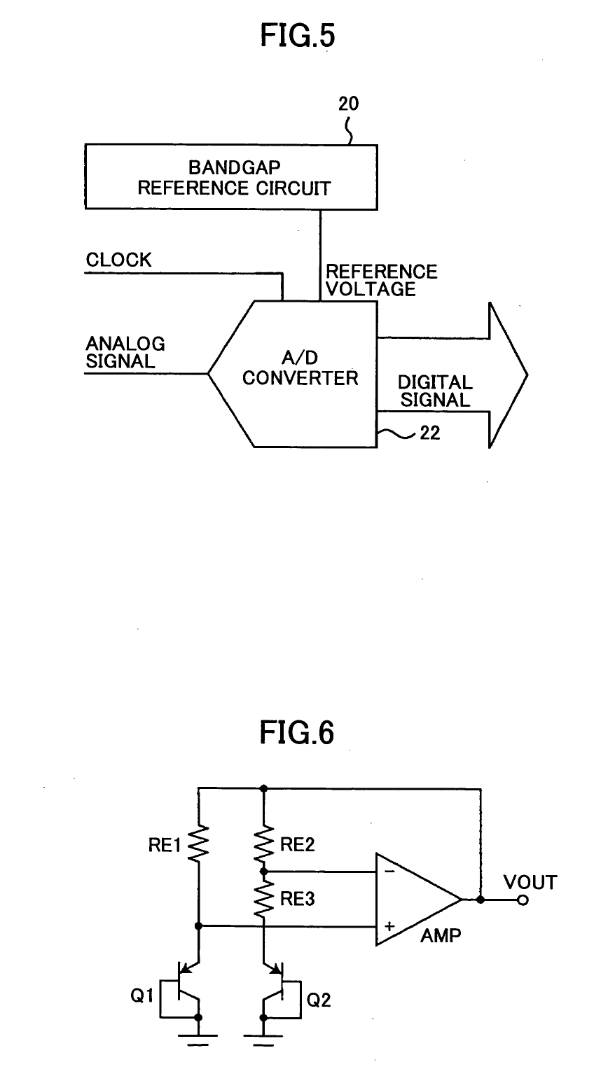

Referring to FIG. 5, a fifth embodiment of the present invention is described. FIG. 5 is a block diagram showing a semiconductor integrated circuit according to the fifth embodiment of the present invention. In FIG. 5, in the semiconductor integrated circuit, a reference voltage generating circuit and a high-speed A/D converter are integrated, and as the reference voltage generating circuit, a bandgap reference circuit is used.

In FIG. 5, a reference voltage output from a bandgap reference circuit 20 is input to an A/D converter 22. The A/D converter 22 converts an analog signal into a digital signal by using the reference voltage. The reference voltage can be formed to be a desirable voltage by using an OP amplifier.

In the above description, bipolar PNP transistors are used; however, the embodiments of the present invention can be applied to any type of bipolar transistors.

Further, the present invention is not limited to the specifically disclosed embodiments, and variations and modifications may be made without departing from the scope of the present invention.

The present invention is based on Japanese Priority Patent Application No. 2005-368149, filed on Dec. 21, 2005, with the Japanese Patent Office, the entire contents of which are hereby incorporated herein by reference.

What is claimed is:

1. A reference voltage generating circuit of a bandgap reference circuit, comprising:
a collector layer where collectors of transistors are disposed;
a base layer where bases of the transistors are disposed and which base layer is formed on the surface of the collector layer; and
a plurality of emitter layers in each of which an emitter of the transistor is disposed and which emitter layers are formed on the surface of the base layer that is common to the emitter layers.

2. The reference voltage generating circuit as claimed in claim 1, wherein:
base electrodes of the bases of the transistors are disposed at inner circumference regions of the base layer.

3. The reference voltage generating circuit as claimed in claim 1, wherein:
the shape of the emitter layer is made octagonal by cutting off a corner part of the emitter layer having a square shape and base electrodes of the bases are disposed at the positions where the corner parts of the emitter layers are cut off.

4. The reference voltage generating circuit as claimed in claim 3, wherein:
the base electrodes are not disposed at the inner circumference regions of the base layer and the area of the base layer is narrowed so as to shorten the distance between the outer circumference of the base layer and the emitter layers.

5. The reference voltage generating circuit as in claim 4, wherein:
the shape of the base layer is made octagonal by cutting off corner parts of the base layer having a square shape.

6. A semiconductor integrated circuit, comprising:
a high-speed circuit; and
a reference voltage generating circuit; wherein
the reference voltage generating circuit includes
a collector layer where collectors of transistors are disposed;
a base layer where bases of the transistors are disposed and which base layer is formed on the surface of the collector layer; and
a plurality of emitter layers in each of which an emitter of the transistor is disposed and which emitter layers are formed on the surface of the base layer that is common to the emitter layers.

7. The semiconductor integrated circuit as claimed in claim 6, wherein:
base electrodes of the bases of the transistors are disposed at inner circumference regions of the base layer in the reference voltage generating circuit.

8. The semiconductor integrated circuit as claimed in claim 6, wherein:
the shape of the emitter layer is made octagonal by cutting off a corner part of the emitter layer having a square shape and base electrodes of the bases are disposed at the positions where the corner parts of the emitter layers are cut off in the reference voltage generating circuit.

9. The semiconductor integrated circuit as claimed in claim 8, wherein:
the base electrodes are not disposed at the inner circumference regions of the base layer and the area of the base layer is narrowed so as to shorten the distance between the outer circumference of the base layer and the emitter layers in the reference voltage generating circuit.

10. The semiconductor integrated circuit as in claim 9, wherein:
the shape of the base layer is made octagonal by cutting off corner parts of the base layer having a square shape in the reference voltage generating circuit.
